(19) United States
(12) Patent Application Publication
(10) Pub. No.: US 2024/0389400 A1
(43) Pub. Date: Nov. 21, 2024

(54) DISPLAY DEVICE AND MANUFACTURING METHOD OF DISPLAY DEVICE

(71) Applicant: Japan Display Inc., Tokyo (JP)

(72) Inventors: Naoya IWAHASHI, Tokyo (JP); Ryota TAKASAKI, Tokyo (JP); Sho YANAGISAWA, Tokyo (JP); Kazumi IIZAWA, Tokyo (JP)

(73) Assignee: Japan Display Inc., Tokyo (JP)

(21) Appl. No.: 18/650,153

(22) Filed: Apr. 30, 2024

(30) Foreign Application Priority Data
May 17, 2023 (JP) 2023-081274

(51) Int. Cl. H10K 59/122; H10K 59/12; H10K 71/16; H10K 71/20; H10K 71/60

(52) U.S. Cl. CPC H10K 59/122; H10K 59/1201; H10K 71/166; H10K 71/231; H10K 71/60

(57) ABSTRACT

According to one embodiment, a display device includes an organic insulating layer provided over a display area and a surrounding area, a lower electrode provided on the organic insulating layer in the display area, an organic layer provided on the lower electrode and including a light emitting layer, an upper electrode provided on the organic layer, a first partition provided in the surrounding area and having a first lower portion and a first upper portion which is provided on the first lower portion and protrudes from a side surface of the first lower portion, and a metal layer provided in the surrounding area and overlapping an aperture of the organic insulating layer. The first partition is provided in the aperture.

### CROSS-REFERENCE TO RELATED APPLICATION

This application is based upon and claims the benefit of priority from Japanese Patent Application No. 2023-081274, filed May 17, 2023, the entire contents of which are incorporated herein by reference.

### FIELD

Embodiments described herein relate generally to a display device and a manufacturing method of a display device.

### BACKGROUND

Recently, display devices to which an organic light emitting diode (OLED) is applied as a display element have been put into practical use. This display element comprises a pixel circuit including a thin-film transistor, a lower electrode connected to the pixel circuit, an organic layer which covers the lower electrode, and an upper electrode which covers the organic layer. The organic layer includes functional layers such as a hole transport layer and an electron transport layer in addition to a light emitting layer.

In the process of manufacturing such a display element, a technique which prevents the reduction in reliability has been required.

### BRIEF DESCRIPTION OF THE DRAWINGS

FIG. 1 is a diagram showing a configuration example of a display device DSP.

FIG. 2 is a diagram showing an example of the layout of subpixels SP1, SP2 and SP3.

FIG. 3 is a schematic cross-sectional view of the display device DSP along the A-B line of FIG. 2.

FIG. 4 is a plan view showing an example of a mother substrate 100 for a display device.

FIG. 5 is a plan view showing a configuration example of a pad PD.

FIG. 6 is a plan view showing a configuration example of a pad area in a surrounding area SA or a margin portion MP.

FIG. 7 is a cross-sectional view of the mother substrate 100 along the C-D line of FIG. 6.

FIG. 8 is a plan view showing another configuration example of the pad area in the surrounding area SA or the margin portion MP.

FIG. 9 is a plan view showing another configuration example of the pad area in the surrounding area SA or the margin portion MP.

FIG. 10 is a cross-sectional view of the mother substrate 100 along the C-D line of FIG. 9.

FIG. 11 is a plan view showing another configuration example of the pad area in the surrounding area SA or the margin portion MP.

FIG. 12 is a plan view showing another configuration example of the pad area in the surrounding area SA or the margin portion MP.

FIG. 13 is a cross-sectional view of the mother substrate 100 along the C-D line of FIG. 12.

FIG. 14A is a cross-sectional view showing a configuration example of a first group.

FIG. 14B is a cross-sectional view showing another configuration example.

FIG. 14C is a cross-sectional view showing another configuration example.

FIG. 15A is a cross-sectional view showing another configuration example.

FIG. 15B is a cross-sectional view showing another configuration example.

FIG. 15C is a cross-sectional view showing another configuration example.

FIG. 16A is a cross-sectional view showing a configuration example of a second group.

FIG. 16B is a cross-sectional view showing another configuration example.

FIG. 16C is a cross-sectional view showing another configuration example.

FIG. 17A is a cross-sectional view showing another configuration example.

FIG. 17B is a cross-sectional view showing another configuration example.

FIG. 17C is a cross-sectional view showing another configuration example.

FIG. 18A is a cross-sectional view showing a configuration example of a third group.

FIG. 18B is a cross-sectional view showing another configuration example.

FIG. 18C is a cross-sectional view showing another configuration example.

FIG. 19A is a cross-sectional view showing another configuration example.

FIG. 19B is a cross-sectional view showing another configuration example.

FIG. 19C is a cross-sectional view showing another configuration example.

FIG. 20 is a diagram for explaining the manufacturing method of the display device DSP.

FIG. 21 is a diagram for explaining the manufacturing method of the display device DSP.

FIG. 22 is a diagram for explaining the manufacturing method of the display device DSP.

FIG. 23 is a diagram for explaining the manufacturing method of the display device DSP.

FIG. 24 is a diagram for explaining the manufacturing method of the display device DSP.

FIG. 25 is a diagram for explaining the manufacturing method of the display device DSP.

FIG. 26 is a cross-sectional view for explaining a state in which a multilayer film 115 is formed in the pad PD shown in FIG. 7.

### DETAILED DESCRIPTION

Embodiments described herein aim to provide a display device which can prevent the reduction in reliability and a manufacturing method of such a display device.

In general, according to one embodiment, a display device comprises a substrate, an organic insulating layer provided over a display area which displays an image and a surrounding area located on an external side relative to the display area above the substrate, a lower electrode provided on the organic insulating layer in the display area, an organic layer provided on the lower electrode and including a light emitting layer, an upper electrode provided on the organic layer, a first partition provided in the surrounding area and having a first lower portion and a first upper portion which is provided on the first lower portion and protrudes from a side surface of the first lower portion, and a metal layer provided in the surrounding area and overlapping an aperture of the organic insulating layer. The first partition is provided in the aperture.

According to another embodiment, a display device comprises a substrate, an organic insulating layer provided over a display area which displays an image and a surrounding area located on an external side relative to the display area above the substrate, a lower electrode provided on the organic insulating layer in the display area, an organic layer provided on the lower electrode and including a light emitting layer, an upper electrode provided on the organic layer, a first partition provided in the surrounding area and having a first lower portion and a first upper portion which is provided on the first lower portion and protrudes from a side surface of the first lower portion, and a metal layer provided in the surrounding area and overlapping an aperture of the organic insulating layer. The first partition is provided above the organic insulating layer.

According to yet another embodiment, a manufacturing method of a display device comprises forming a metal layer above a substrate, forming an organic insulating layer over a display area which displays an image and a surrounding area located on an external side relative to the display area, forming a lower electrode on the organic insulating layer in the display area, forming a first partition having a first lower portion located in the surrounding area and a first upper portion which is located on the first lower portion and protrudes from a side surface of the first lower portion, forming an organic layer including a light emitting layer on the lower electrode, and forming an upper electrode on the organic layer. The forming the organic insulating layer includes a process of forming an aperture overlapping the metal layer in the surrounding area.

The embodiments can provide a display device which can prevent the reduction in reliability and a manufacturing method of such a display device.

Embodiments will be described with reference to the accompanying drawings.

The disclosure is merely an example, and proper changes in keeping with the spirit of the invention, which are easily conceivable by a person of ordinary skill in the art, come within the scope of the invention as a matter of course. In addition, in some cases, in order to make the description clearer, the widths, thicknesses, shapes, etc., of the respective parts are illustrated schematically in the drawings, rather than as an accurate representation of what is implemented. However, such schematic illustration is merely exemplary, and in no way restricts the interpretation of the invention. In addition, in the specification and drawings, structural elements which function in the same or a similar manner to those described in connection with preceding drawings are denoted by like reference numbers, detailed description thereof being omitted unless necessary.

In the drawings, in order to facilitate understanding, an X-axis, a Y-axis and a Z-axis orthogonal to each other are shown depending on the need. A direction parallel to the X-axis is referred to as a first direction X. A direction parallel to the Y-axis is referred to as a second direction Y. A direction parallel to the Z-axis is referred to as a third direction Z. When various elements are viewed parallel to the third direction Z, the appearance is defined as a plan view.

The display device of the embodiment is an organic electroluminescent display device comprising an organic light emitting diode (OLED) as a display element, and could be mounted on a television, a personal computer, a vehicle-mounted device, a tablet, a smartphone, a mobile phone, etc.

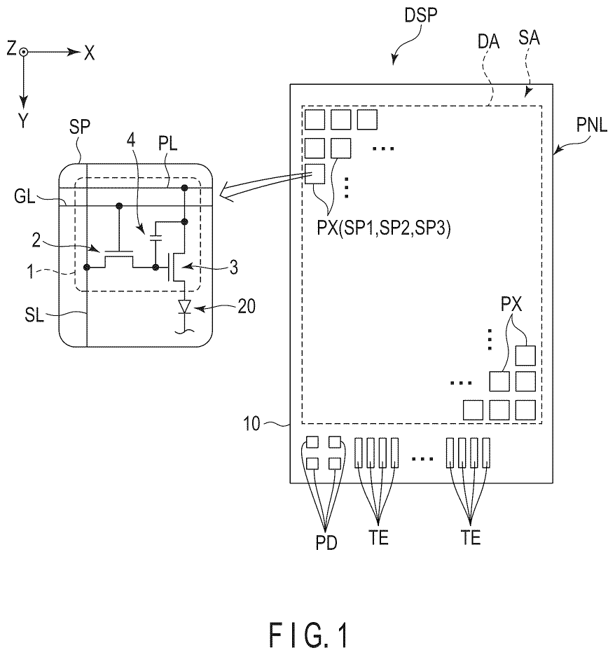

FIG. 1 is a diagram showing a configuration example of a display device DSP.

The display device DSP comprises a display panel PNL having a display area DA which displays an image and a surrounding area SA located on an external side relative to the display area DA on an insulating substrate 10. The substrate 10 may be glass or a resinous film having flexibility.

In the embodiment, the substrate 10 is rectangular in plan view. It should be noted that the shape of the substrate 10 in plan view is not limited to a rectangle and may be another shape such as a square, a circle or an oval.

The display area DA comprises a plurality of pixels PX arrayed in matrix in a first direction X and a second direction Y. Each pixel PX includes a plurality of subpixels SP. For example, each pixel PX includes subpixel SP1 which exhibits a first color, subpixel SP2 which exhibits a second color and subpixel SP3 which exhibits a third color. The first color, the second color and the third color are different colors. Each pixel PX may include a subpixel SP which exhibits another color such as white in addition to subpixels SP1, SP2 and SP3 or instead of one of subpixels SP1, SP2 and SP3.

Each subpixel SP comprises a pixel circuit 1 and a display element 20 driven by the pixel circuit 1. The pixel circuit 1 comprises a pixel switch 2, a drive transistor 3 and a capacitor 4. The pixel switch 2 and the drive transistor 3 are, for example, switching elements consisting of a thin-film transistor.

The gate electrode of the pixel switch 2 is connected to a scanning line GL. One of the source electrode and the drain electrode of the pixel switch 2 is connected to a signal line SL. The other one is connected to the gate electrode of the drive transistor 3 and the capacitor 4. In the drive transistor 3, one of the source electrode and the drain electrode is connected to a power line PL and the capacitor 4, and the other one is connected to the anode of the display element 20.

It should be noted that the configuration of the pixel circuit 1 is not limited to the example shown in the figure. For example, the pixel circuit 1 may comprise more thin-film transistors and capacitors.

The display element 20 is an organic light emitting diode (OLED) as a light emitting element, and may be called an organic EL element.

The surrounding area SA comprises a plurality of terminals TE for connecting an IC chip and a flexible printed circuit. The terminals TE are arranged in a single direction. In the example shown in the figure, the terminals TE are arranged in the first direction X. In the example shown in the figure, the surrounding area SA has pads PD used for inspection, etc. It should be noted that the pads PD may be omitted in the display panel PNL.

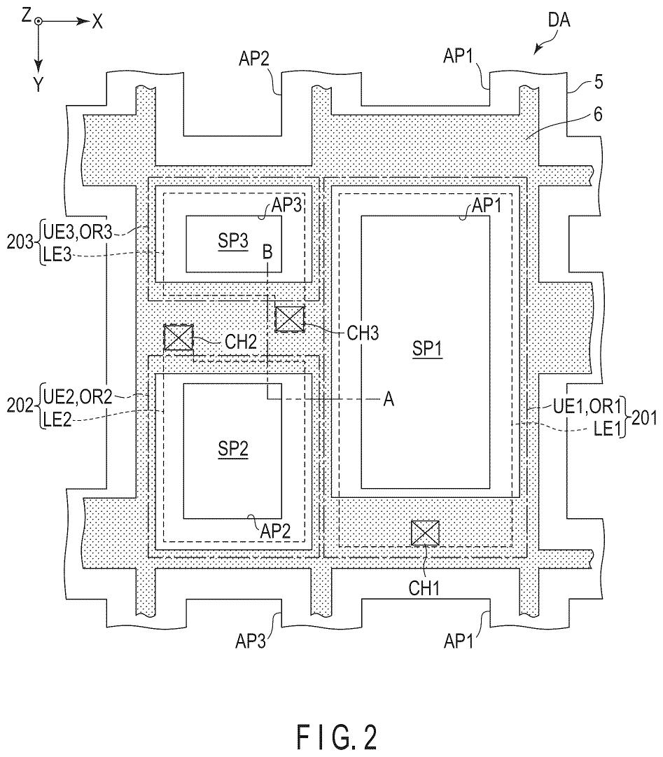

FIG. 2 is a diagram showing an example of the layout of subpixels SP1, SP2 and SP3.

In the example of FIG. 2, subpixels SP2 and SP3 are arranged in the second direction Y. Subpixels SP1 and SP2 are arranged in the first direction X, and subpixels SP1 and SP3 are arranged in the first direction X.

When subpixels SP1, SP2 and SP3 are provided in line with this layout, a column in which subpixels SP2 and SP3 are alternately provided in the second direction Y and a column in which a plurality of subpixels SP1 are provided in the second direction Y are formed in the display area DA. These columns are alternately arranged in the first direction X.

It should be noted that the layout of subpixels SP1, SP2 and SP3 is not limited to the example of FIG. 2. As another example, subpixels SP1, SP2 and SP3 in each pixel PX may be arranged in order in the first direction X.

An inorganic insulating layer 5 and a partition 6 are provided in the display area DA. The inorganic insulating layer 5 has apertures AP1, AP2 and AP3 in subpixels SP1, SP2 and SP3, respectively. The inorganic insulating layer 5 having these apertures AP1, AP2 and AP3 may be called a rib.

The partition 6 overlaps the inorganic insulating layer 5 in plan view. The partition 6 is formed into a grating shape surrounding the apertures AP1, AP2 and AP3. In other words, the partition 6 has apertures in subpixels SP1, SP2 and SP3 in a manner similar to that of the inorganic insulating layer 5.

Subpixels SP1, SP2 and SP3 comprise display elements 201, 202 and 203, respectively, as the display elements 20.

The display element 201 of subpixel SP1 comprises a lower electrode LE1, an upper electrode UE1 and an organic layer OR1 overlapping the aperture AP1. The peripheral portion of the lower electrode LE1 is covered with the inorganic insulating layer 5. The display element 201 comprising the lower electrode LE1, the organic layer OR1 and the upper electrode UE1 is surrounded by the partition 6 in plan view. The peripheral portion of each of the organic layer OR1 and the upper electrode UE1 overlaps the inorganic insulating layer 5 in plan view. The organic layer OR1 includes a light emitting layer which emits light in, for example, a blue wavelength range.

The display element 202 of subpixel SP2 comprises a lower electrode LE2, an upper electrode UE2 and an organic layer OR2 overlapping the aperture AP2. The peripheral portion of the lower electrode LE2 is covered with the inorganic insulating layer 5. The display element 202 comprising the lower electrode LE2, the organic layer OR2 and the upper electrode UE2 is surrounded by the partition 6 in plan view. The peripheral portion of each of the organic layer OR2 and the upper electrode UE2 overlaps the inorganic insulating layer 5 in plan view. The organic layer OR2 includes a light emitting layer which emits light in, for example, a green wavelength range.

The display element 203 of subpixel SP3 comprises a lower electrode LE3, an upper electrode UE3 and an organic layer OR3 overlapping the aperture AP3. The peripheral portion of the lower electrode LE3 is covered with the inorganic insulating layer 5. The display element 203 comprising the lower electrode LE3, the organic layer OR3 and the upper electrode UE3 is surrounded by the partition 6 in plan view. The peripheral portion of each of the organic layer OR3 and the upper electrode UE3 overlaps the inorganic insulating layer 5 in plan view. The organic layer OR3 includes a light emitting layer which emits light in, for example, a red wavelength range.

In the example of FIG. 2, the outer shapes of the lower electrodes LE1, LE2 and LE3 are shown by dotted lines, and the outer shapes of the organic layers OR1, OR2 and OR3 and the upper electrodes UE1, UE2 and UE3 are shown by alternate long and short dash lines. It should be noted that the outer shape of each of the lower electrodes, organic layers and upper electrodes shown in the figure does not necessarily reflect the accurate shape.

The lower electrodes LE1, LE2 and LE3 correspond to, for example, the anodes of the display elements. The upper electrodes UE1, UE2 and UE3 correspond to the cathodes of the display elements or a common electrode.

The lower electrode LE1 is connected to the pixel circuit 1 (see FIG. 1) of subpixel SP1 through a contact hole CH1. The lower electrode LE2 is connected to the pixel circuit 1 of subpixel SP2 through a contact hole CH2. The lower electrode LE3 is connected to the pixel circuit 1 of subpixel SP3 through a contact hole CH3.

In the example of FIG. 2, the area of the aperture AP1, the area of the aperture AP2 and the area of the aperture AP3 are different from each other. The area of the aperture AP1 is greater than that of the aperture AP2, and the area of the aperture AP2 is greater than that of the aperture AP3. In other words, the area of the lower electrode LE1 exposed from the aperture AP1 is greater than that of the lower electrode LE2 exposed from the aperture AP2. The area of the lower electrode LE2 exposed from the aperture AP2 is greater than that of the lower electrode LE3 exposed from the aperture AP3.

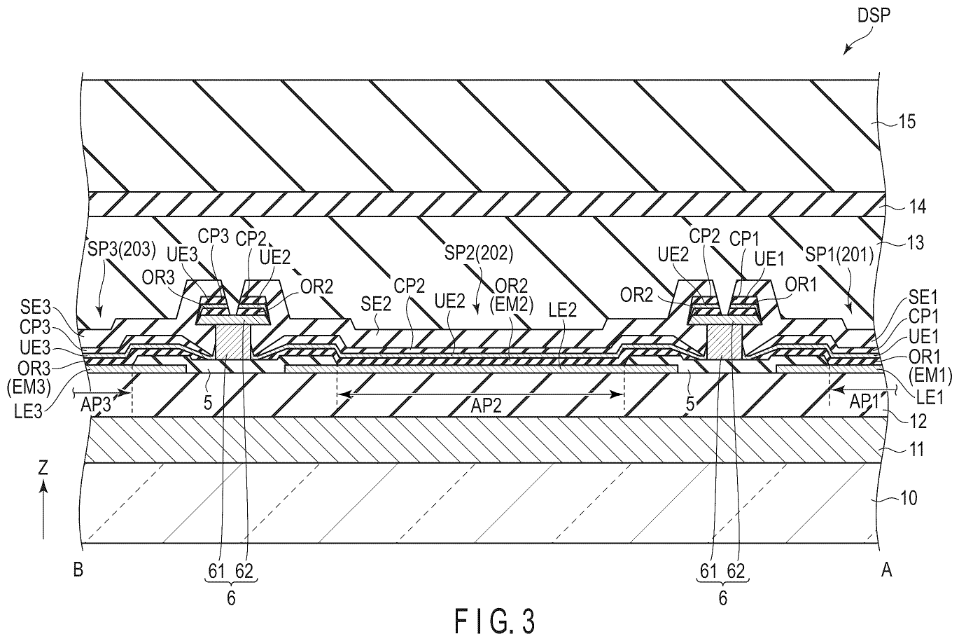

FIG. 3 is a schematic cross-sectional view of the display device DSP along the A-B line of FIG. 2.

A circuit layer 11 is provided on the substrate 10. The circuit layer 11 includes various circuits such as the pixel circuit 1 shown in FIG. 1 and various lines such as the scanning line GL, the signal line SL and the power line PL. The circuit layer 11 is covered with an insulating layer 12. The insulating layer 12 is an organic insulating layer which planarizes the irregularities formed by the circuit layer 11.

The lower electrodes LE1, LE2 and LE3 are provided on the insulating layer 12 and are spaced apart from each other. The inorganic insulating layer 5 is provided on the insulating layer 12 and the lower electrodes LE1, LE2 and LE3. The aperture AP1 of the inorganic insulating layer 5 overlaps the lower electrode LE1. The aperture AP2 overlaps the lower electrode LE2. The aperture AP3 overlaps the lower electrode LE3. The peripheral portions of the lower electrodes LE1, LE2 and LE3 are covered with the inorganic insulating layer 5. The insulating layer 12 is covered with the inorganic insulating layer 5 between, of the lower electrodes LE1, LE2 and LE3, the lower electrodes which are adjacent to each other. The lower electrodes LE1, LE2 and LE3 are connected to the pixel circuits 1 of subpixels SP1, SP2 and SP3, respectively, through the contact holes provided in the insulating layer 12. It should be noted that, although the contact holes of the insulating layer 12 are omitted in FIG. 3, the contact holes correspond to the contact holes CH1, CH2 and CH3 of FIG. 2.

The partition 6 includes a conductive lower portion (stem) 61 provided on the inorganic insulating layer 5 and an upper portion (shade) 62 provided on the lower portion 61. The lower portion 61 of the partition 6 shown on the right side of the figure is located between the aperture AP1 and the aperture AP2. The lower portion 61 of the partition 6 shown on the left side of the figure is located between the aperture AP2 and the aperture AP3. The upper portion 62 has a width greater than that of the lower portion 61. The both end portions of the upper portion 62 protrude relative to the side surfaces of the lower portion 61. This shape of the partition 6 is called an overhang shape.

The organic layer OR1 is in contact with the lower electrode LE1 through the aperture AP1 and covers the lower electrode LE1 exposed from the aperture AP1. The peripheral portion of the organic layer OR1 is located on the inorganic insulating layer 5. The upper electrode UE1 covers the organic layer OR1 and is in contact with the lower portion 61.

The organic layer OR2 is in contact with the lower electrode LE2 through the aperture AP2 and covers the lower electrode LE2 exposed from the aperture AP2. The peripheral portion of the organic layer OR2 is located on the inorganic insulating layer 5. The upper electrode UE2 covers the organic layer OR2 and is in contact with the lower portion 61.

The organic layer OR3 is in contact with the lower electrode LE3 through the aperture AP3 and covers the lower electrode LE3 exposed from the aperture AP3. The peripheral portion of the organic layer OR3 is located on the inorganic insulating layer 5. The upper electrode UE3 covers the organic layer OR3 and is in contact with the lower portion 61.

In the example of FIG. 3, subpixel SP1 has a cap layer CP1 and a sealing layer SE1. Subpixel SP2 has a cap layer CP2 and a sealing layer SE2. Subpixel SP3 has a cap layer CP3 and a sealing layer SE3. The cap layers CP1, CP2 and CP3 function as optical adjustment layers which improve the extraction efficiency of the light emitted from the organic layers OR1, OR2 and OR3, respectively.

The cap layer CP1 is provided on the upper electrode UE1.

The cap layer CP2 is provided on the upper electrode UE2.

The cap layer CP3 is provided on the upper electrode UE3.

The sealing layer SE1 is provided on the cap layer CP1, is in contact with the partition 6 and continuously covers the members of subpixel SP1.

The sealing layer SE2 is provided on the cap layer CP2, is in contact with the partition 6 and continuously covers the members of subpixel SP2.

The sealing layer SE3 is provided on the cap layer CP3, is in contact with the partition 6 and continuously covers the members of subpixel SP3.

In the example of FIG. 3, each of the organic layer OR1, the upper electrode UE1 and the cap layer CP1 is partly located on the partition 6 around subpixel SP1. These portions are spaced apart from, of the organic layer OR1, the upper electrode UE1 and the cap layer CP1, the portions located in the aperture AP1 (the portions constituting the display element 201).

Similarly, each of the organic layer OR2, the upper electrode UE2 and the cap layer CP2 is partly located on the partition 6 around subpixel SP2. These portions are spaced apart from, of the organic layer OR2, the upper electrode UE2 and the cap layer CP2, the portions located in the aperture AP2 (the portions constituting the display element 202).

Similarly, each of the organic layer OR3, the upper electrode UE3 and the cap layer CP3 is partly located on the partition 6 around subpixel SP3. These portions are spaced apart from, of the organic layer OR3, the upper electrode UE3 and the cap layer CP3, the portions located in the aperture AP3 (the portions constituting the display element 203).

The end portions of the sealing layers SE1, SE2 and SE3 are located above the partition 6. In the example of FIG. 3, the end portions of the sealing layers SE1 and SE2 located above the partition 6 between subpixels SP1 and SP2 are spaced apart from each other. The end portions of the sealing layers SE2 and SE3 located above the partition 6 between subpixels SP2 and SP3 are spaced apart from each other.

The sealing layers SE1, SE2 and SE3 are covered with a resin layer 13. The resin layer 13 is covered with a sealing layer 14. The sealing layer 14 is covered with a resin layer 15.

Each of the inorganic insulating layer 5, the sealing layers SE1, SE2 and SE3 and the sealing layer 14 is formed of, for example, an inorganic insulating material such as silicon nitride (SiNx), silicon oxide (SiOx), silicon oxynitride (SiON) or aluminum oxide (Al₂O₃).

The lower portion 61 of the partition 6 is formed of a conductive material and is electrically connected to the upper electrodes UE1, UE2 and UE3. The upper portion 62 of the partition 6 is formed of, for example, a conductive material. However, the upper portion 62 may be formed of an insulating material. The lower portion 61 is formed of a material which is different from that of the upper portion 62.

For example, each of the lower electrodes LE1, LE2 and LE3 is a multilayer body including a transparent electrode formed of an oxide conductive material such as indium tin oxide (ITO) and a metal electrode formed of a metal material such as silver.

The organic layer OR1 includes a light emitting layer EM1. The organic layer OR2 includes a light emitting layer EM2. The organic layer OR3 includes a light emitting layer EM3. The light emitting layer EM1, the light emitting layer EM2 and the light emitting layer EM3 are formed of materials which are different from each other. For example, the light emitting layer EM1 is formed of a material which emits light in a blue wavelength range. The light emitting layer EM2 is formed of a material which emits light in a green wavelength range. The light emitting layer EM3 is formed of a material which emits light in a red wavelength range.

Each of the organic layers OR1, OR2 and OR3 includes a plurality of functional layers such as a hole injection layer, a hole transport layer, an electron blocking layer, a hole blocking layer, an electron transport layer and an electron injection layer.

Each of the upper electrodes UE1, UE2 and UE3 is formed of, for example, a metal material such as an alloy of magnesium and silver (MgAg).

Each of the cap layers CP1, CP2 and CP3 is a multilayer body consisting of a plurality of thin films. All of the thin films are transparent and have refractive indices different from each other.

The circuit layer 11, insulating layer 12 and inorganic insulating layer 5 shown in FIG. 3 are provided over the display area DA and the surrounding area SA.

Now, this specification explains a mother substrate 100 for a display device for manufacturing a plurality of display devices DSP in a lump.

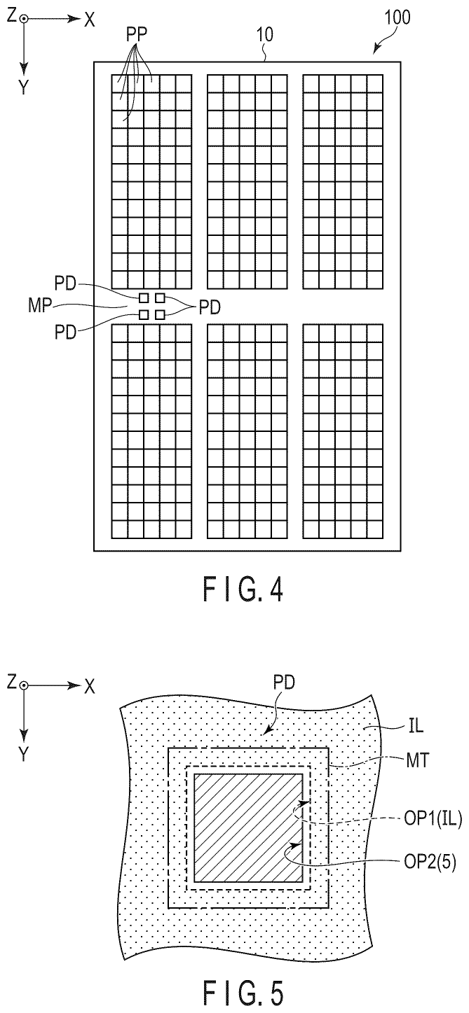

FIG. 4 is a plan view showing an example of the mother substrate 100 for a display device.

The mother substrate 100 comprises a plurality of panel portions PP and a margin portion MP provided on an external side relative to these panel portions PP on a large substrate 10. The large substrate 10 is formed into, for example, a rectangular shape. The panel portions PP are arrayed in matrix in the first direction X and the second direction Y. The panel portions PP are extracted by dividing the mother substrate 100 along cut lines. Each of the extracted panel portions PP corresponds to the display panel PNL shown in FIG. 1 and comprises the display area DA and the surrounding area SA.

The margin portion MP comprises, for example, a plurality of pads PD electrically connected to a test element group, etc.

FIG. 5 is a plan view showing a configuration example of a pad PD.

The pad PD shown in the figure corresponds to each pad PD of the surrounding area SA shown in FIG. 1 or each pad PD of the margin portion MP shown in FIG. 4.

The metal layer MT shown by dashed lines corresponds to the electrode of the pad PD. The metal layer MT overlaps the aperture OP1 of an organic insulating layer IL and the aperture OP2 of the inorganic insulating layer 5. The aperture OP1 is shown by dotted lines. The aperture OP2 is shown by solid lines. In the metal layer MT, the portion exposed from the aperture OP1 and the aperture OP2 is shown by hatch lines. The peripheral portion of the metal layer MT is covered with the organic insulating layer IL and the inorganic insulating layer 5.

The organic insulating layer IL includes at least the insulating layer 12 shown in FIG. 3. The organic insulating layer IL and the inorganic insulating layer 5 are provided in each of the panel portions PP and are provided in the margin portion MP as well.

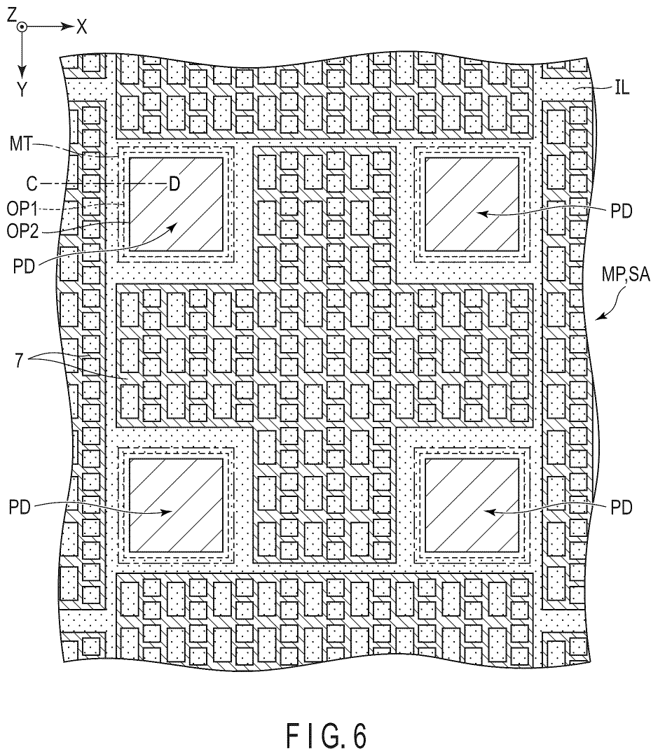

FIG. 6 is a plan view showing a configuration example of a pad area in the surrounding area SA or the margin portion MP.

In the example shown in the figure, the pad area includes four pads PD. The metal layer MT of each pad PD is exposed from the aperture OP1 and the aperture OP2.

A partition 7 is provided in a cross-shaped area surrounded by the four pads PD. Further, a partition 7 is provided in an area around the four pads PD. These partitions 7 do not overlap the apertures OP1 and are provided above the organic insulating layer IL. In the example shown in the figure, the partitions 7 do not overlap the pads PD. These partitions 7 are formed into a grating shape. For example, the partitions 7 are formed into the same pattern as the partition 6 shown in FIG. 2 and having a grating shape.

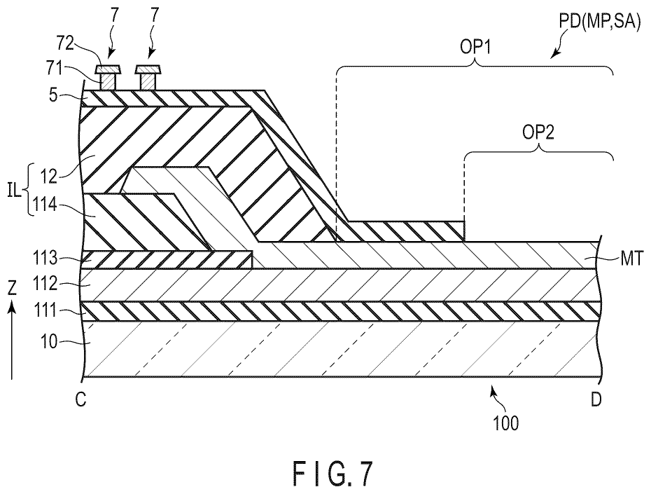

FIG. 7 is a cross-sectional view of the mother substrate 100 along the C-D line of FIG. 6.

An insulating layer 111 is an inorganic insulating layer and is provided on the substrate 10. A wiring layer 112 is provided on the insulating layer 111. An insulating layer 113 is an inorganic insulating layer and is provided on the wiring layer 112. The wiring layer 112 is exposed from the insulating layer 113 in the pad PD. An insulating layer 114 is an organic insulating layer and is provided on the insulating layer 113. The metal layer MT is provided on the insulating layer 113 and the insulating layer 114 and is in contact with the wiring layer 112 in the pad PD. By this configuration, the metal layer MT is electrically connected to the wiring layer 112. These insulating layer 111, wiring layer 112, insulating layer 113, insulating layer 114 and metal layer MT are included in the circuit layer 11 shown in FIG. 3. It should be noted that the circuit layer 11 may include an insulating layer and a conductive layer in addition to the layers shown in FIG. 7.

The insulating layer 12 is an organic insulating layer and is provided on the insulating layer 114 and the metal layer MT. The insulating layer 12 has the aperture OP1 from which the metal layer MT is exposed. The organic insulating layer IL described above has the insulating layer 114 and the insulating layer 12. In this configuration example, the insulating layer 114 corresponds to a first layer, and the insulating layer 12 corresponds to a second layer located on the first layer. The aperture OP1 corresponds to the aperture of the organic insulating layer IL.

The inorganic insulating layer 5 covers the insulating layer 12 and is in contact with the metal layer MT. The inorganic insulating layer 5 has the aperture OP2 which overlaps the aperture OP1. The metal layer MT is exposed from the inorganic insulating layer 5 in the aperture OP2. The area of the aperture OP2 is less than that of the aperture OP1.

The partition 7 is provided above the organic insulating layer IL. The partition 7 has a lower portion 71 provided on the inorganic insulating layer 5 and an upper portion 72 provided on the lower portion 71. The upper portion 72 has a width which is greater than that of the lower portion 71. The both end portions of the upper portion 72 protrude relative to the side surfaces of the lower portion 71. Thus, the partition 7 has an overhang shape similar to that of the partition 6 shown in FIG. 3. The partition 7 can be formed in the same process as the partition 6. In this case, the lower portion 71 is formed of the same material as the lower portion 61. The upper portion 72 is formed of the same material as the upper portion 62.

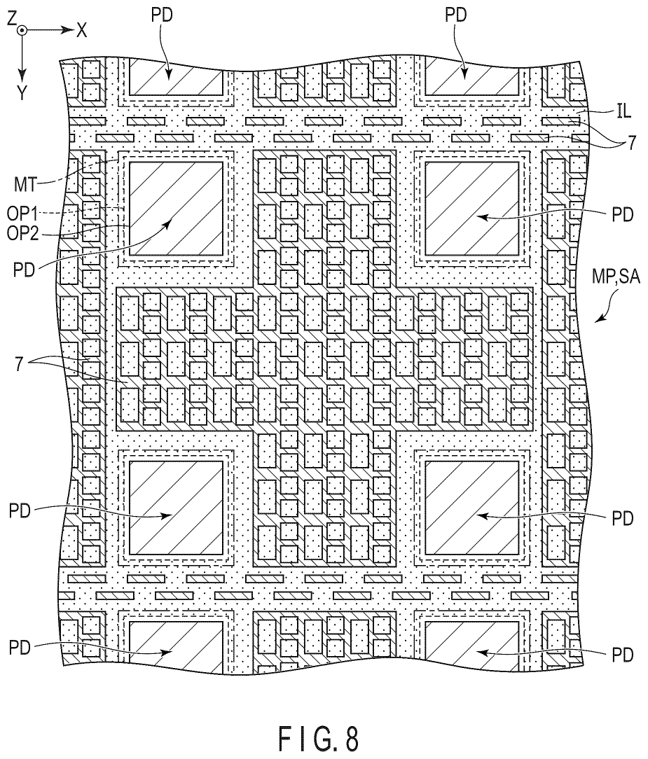

FIG. 8 is a plan view showing another configuration example of the pad area in the surrounding area SA or the margin portion MP.

The configuration example shown in FIG. 8 is different from the configuration example shown in FIG. 6 in respect that linear partitions 7 are added in a space which is comparatively small between adjacent pads PD.

In the example shown in the figure, each partition 7 is formed into a linear shape extending in the first direction X in a small space between pads PD which are adjacent to each other in the second direction Y. The linear partitions 7 are arranged in a staggered manner and provided above the organic insulating layer IL.

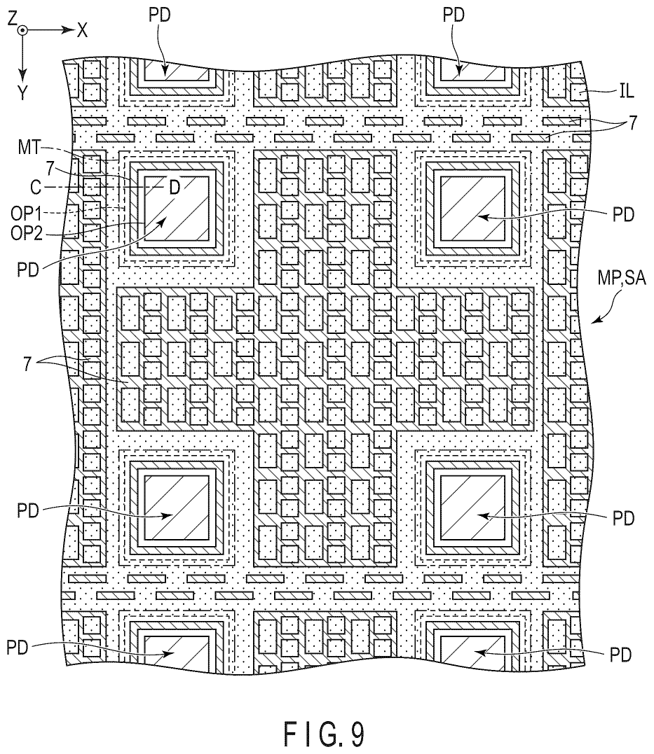

FIG. 9 is a plan view showing another configuration example of the pad area in the surrounding area SA or the margin portion MP.

The configuration example shown in FIG. 9 is different from the configuration example shown in FIG. 8 in respect that a partition 7 provided in the aperture OP1 of the organic insulating layer IL is added.

In plan view, the partition 7 provided in the aperture OP1 overlaps the metal layer MT of the pad PD, is located on an external side relative to the aperture OP2 and is formed into a loop shape along the rim of the aperture OP1. The partition 7 provided above the organic insulating layer IL is spaced apart from the partition 7 provided in the aperture OP1.

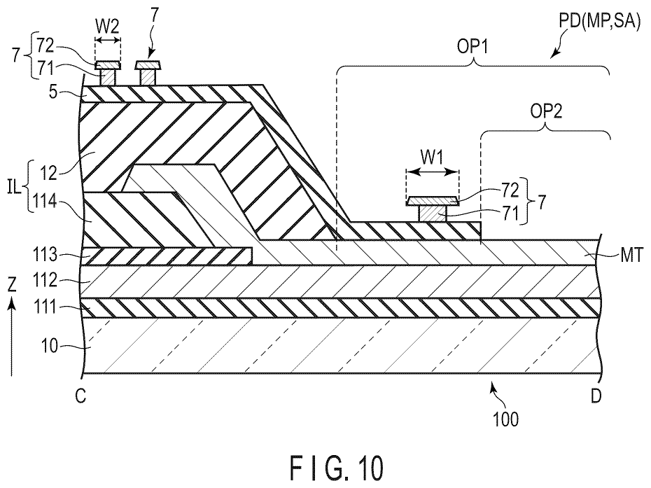

FIG. 10 is a cross-sectional view of the mother substrate 100 along the C-D line of FIG. 9.

Each of the partition 7 provided above the organic insulating layer IL and the partition 7 provided in the aperture OP1 has a lower portion 71 provided on the inorganic insulating layer 5 and an upper portion 72 provided on the lower portion 71 and protruding from the side surfaces of the lower portion 71, and has an overhang shape.

To prevent the partition 7 provided in the aperture OP1 from being lost by excessively removing the partition 7 in wet etching at the time of forming the partitions 7, width W1 of the partition 7 provided in the aperture OP1 should be preferably greater than width W2 of the partition 7 provided above the organic insulating layer IL.

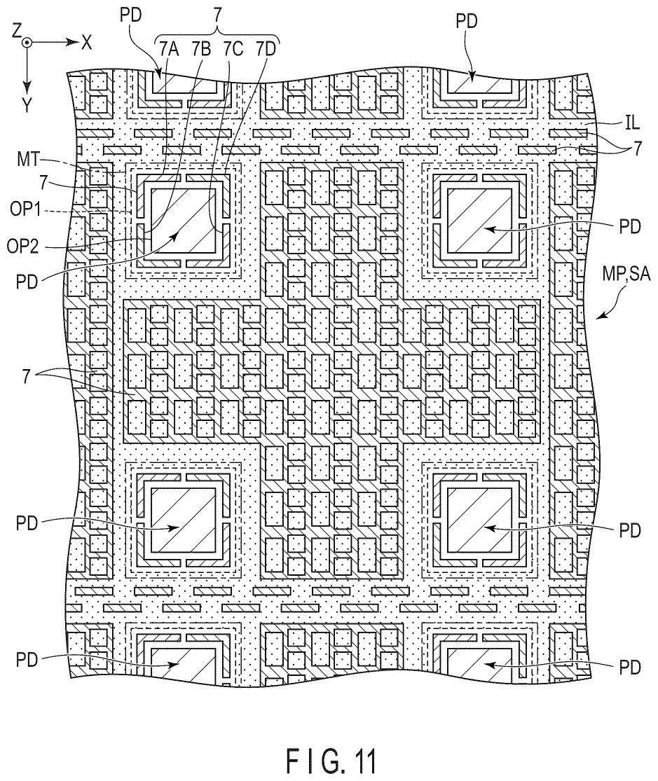

FIG. 11 is a plan view showing another configuration example of the pad area in the surrounding area SA or the margin portion MP.

The configuration example shown in FIG. 11 is different from the configuration example shown in FIG. 9 in respect that the partition 7 provided in the aperture OP1 of the organic insulating layer IL has a plurality of segments formed along the rim of the aperture OP1.

In the example shown in the figure, the partition 7 has four segments 7A, 7B, 7C and 7D spaced apart from each other. Each of the four segments 7A, 7B, 7C and 7D is formed into an L-shape. However, the shape is not limited to this example.

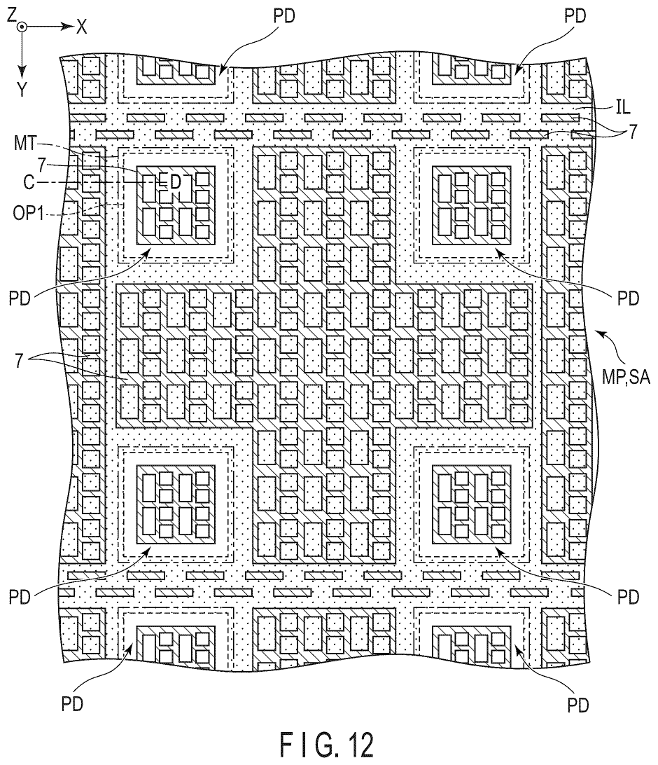

FIG. 12 is a plan view showing another configuration example of the pad area in the surrounding area SA or the margin portion MP.

The configuration example shown in FIG. 12 is different from the configuration example shown in FIG. 9 in respect that the partition 7 provided in the aperture OP1 of the organic insulating layer IL is formed into a grating shape. It should be noted that the aperture OP2 of the organic insulating layer 5 is not present in the configuration example shown here. For example, the partition 7 provided in the aperture OP1 is formed into the same pattern as the partition 7 provided on the organic insulating layer IL.

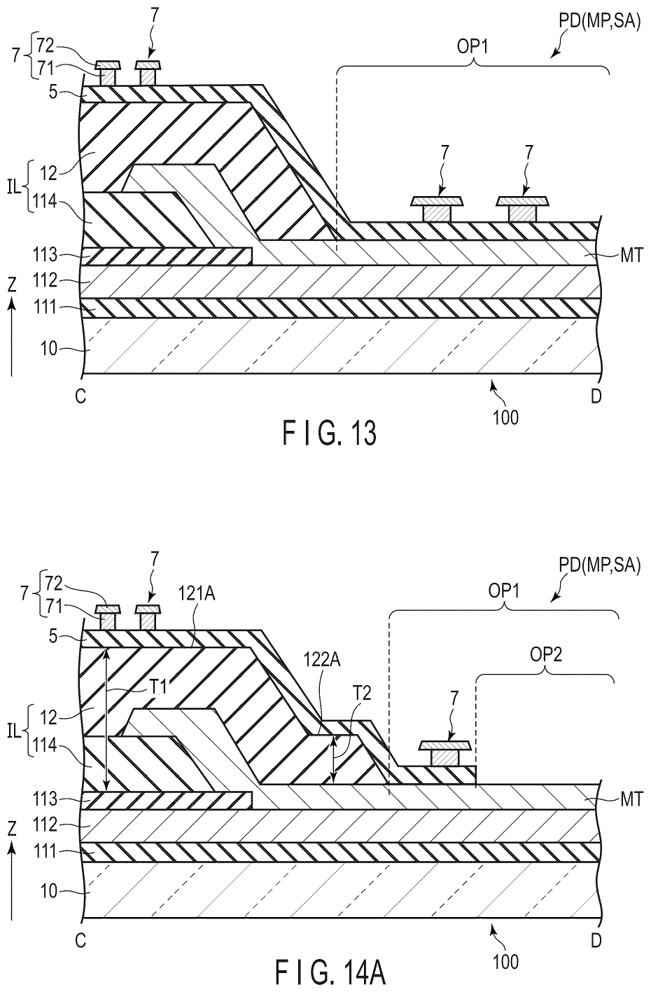

FIG. 13 is a cross-sectional view of the mother substrate 100 along the C-D line of FIG. 12.

The inorganic insulating layer 5 covers the insulating layer 12 and also covers the metal layer MT exposed from the aperture OP1. In other words, as the inorganic insulating layer 5 does not have an aperture, the metal layer MT is not exposed.

The partition 7 provided in the aperture OP1 and having a grating shape is provided on the inorganic insulating layer 5 and is not in contact with the metal layer MT.

Now, this specification explains yet other configuration examples of the cross-sectional structure of the mother substrate 100 including a pad PD.

### [First Group]

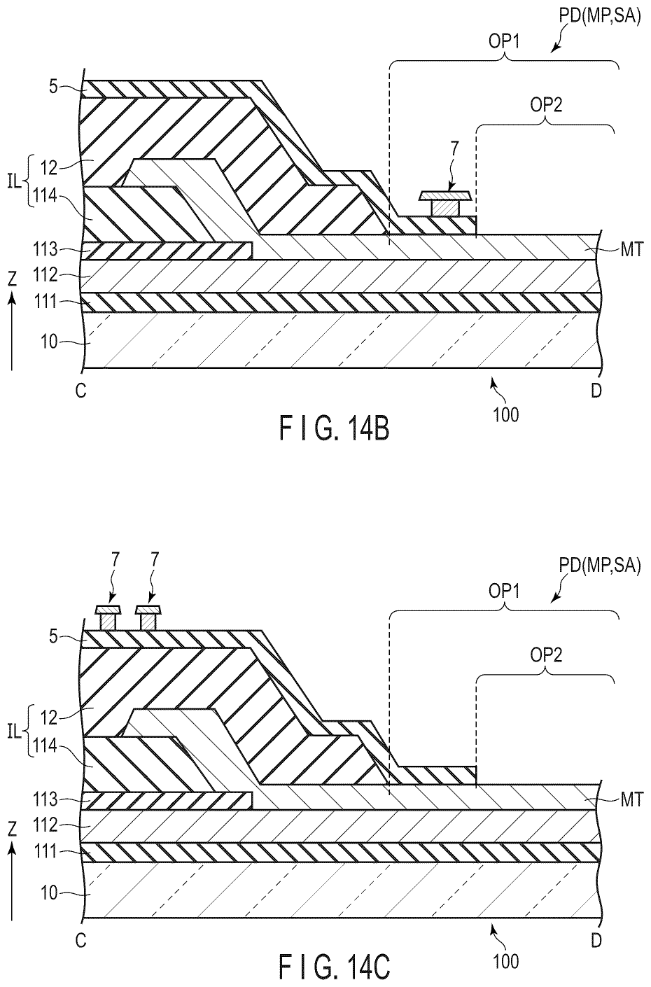

FIG. 14A is a cross-sectional view showing a configuration example of a first group.

The organic insulating layer IL has the insulating layer 114 and the insulating layer 12. In this configuration example, the insulating layer 114 corresponds to the first layer, and the insulating layer 12 corresponds to the second layer located on the first layer. The insulating layer 12 has the aperture OP1.

When this specification focuses attention on the cross-sectional shape of this organic insulating layer IL, the organic insulating layer IL has a stepwise cross section in which the thickness decreases toward the aperture OP1.

Thickness T1 of the organic insulating layer IL is the sum of the thickness of the insulating layer 114 and the thickness of the insulating layer 12 and corresponds to the length from the upper surface of the insulating layer 113 to substantially a flat upper surface 121A of the insulating layer 12 in a third direction Z.

Thickness T2 of the organic insulating layer IL is the thickness of the insulating layer 12 between the insulating layer 114 and the aperture OP1 and corresponds to the length from the upper surface of the metal layer MT to substantially a flat upper surface 122A of the insulating layer 12 in the third direction Z. Thickness T2 is less than thickness T1. The upper surface 122A is located between the upper surface 121A and the aperture OP1 and is located on the lower side than the upper surface 121A.

The inorganic insulating layer 5 covers the insulating layer 12 and has the aperture OP2 from which the metal layer MT is exposed.

The partitions 7 are provided on the inorganic insulating layer 5 above the organic insulating layer IL and in the aperture OP1. In the example shown in the figure, the partition 7 is provided above the upper surface 121A. However, the partition 7 is not provided above the upper surface 122A. It should be noted that the partition 7 may be provided above the upper surface 122A.

The organic insulating layer IL having a stepwise cross section can be formed by, for example, the following method.

First, the insulating layer 114 is formed on the insulating layer 113. Subsequently, the metal layer MT is formed. Subsequently, the insulating layer 12 having the aperture OP1, the upper surface 121A and the upper surface 122A is formed. This insulating layer 12 can be formed by, for example, the following method.

Specifically, for example, an insulating layer is formed by a positive organic material on the whole surface of the mother substrate 100 in which the metal layer MT is formed. Subsequently, the insulating layer is exposed to light. In this exposure process, the amount of exposure of the aperture OP1 is set so as to be the maximum value, and the amount of exposure is set so as to decrease in stages from the aperture OP1 toward the external side. Subsequently, the exposed insulating layer is developed. Subsequently, the insulating layer is baked.

By this process, the organic insulating layer IL having the cross-sectional shape described above is formed.

FIG. 14B is a cross-sectional view showing another configuration example.

The configuration example shown in FIG. 14B is different from the configuration example shown in FIG. 14A in respect that the partition 7 located above the organic insulating layer IL is omitted. The partition 7 is provided on the inorganic insulating layer 5 in the aperture OP1.

In FIG. 14A and FIG. 14B, the shape of the partition 7 provided in the aperture OP1 may be either one of the shapes shown in FIG. 9 and FIG. 11.

FIG. 14C is a cross-sectional view showing another configuration example.

FIG. 14C is different from the configuration example shown in FIG. 14A in respect that the partition 7 provided in the aperture OP1 is omitted. The partition 7 is provided on the inorganic insulating layer 5 above the organic insulating layer IL.

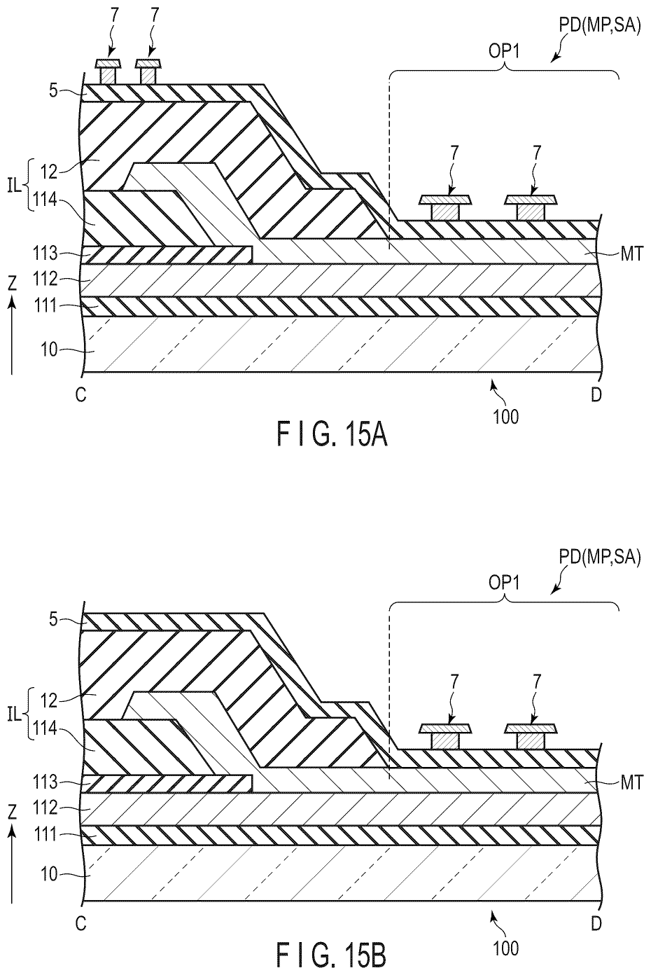

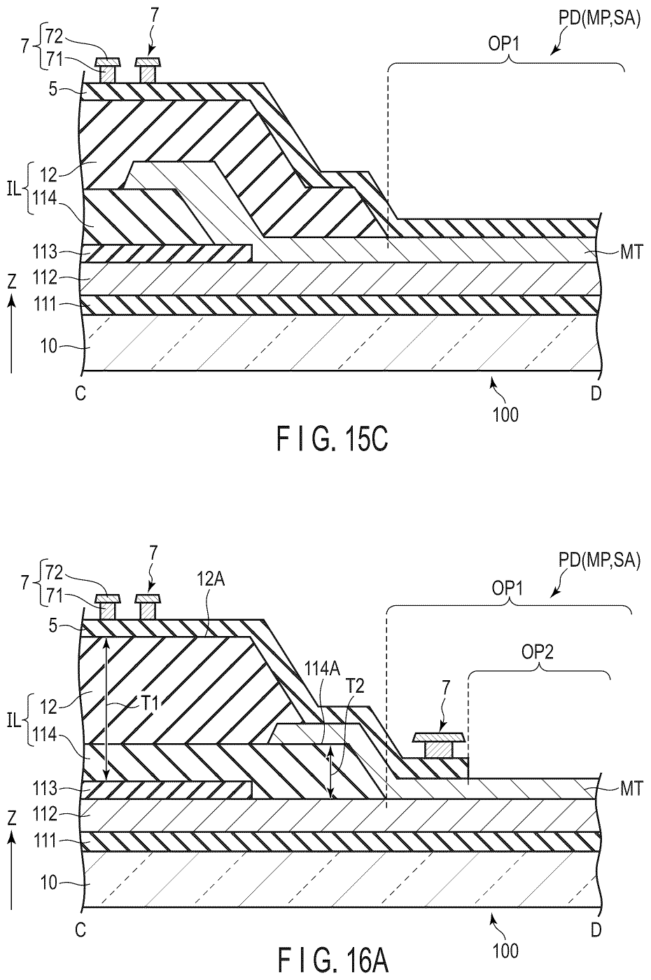

FIG. 15A is a cross-sectional view showing another configuration example.

The configuration example shown in FIG. 15A is different from the configuration example shown in FIG. 14A in respect that no aperture is present in the inorganic insulating layer 5. The partitions 7 are provided on the inorganic insulating layer 5 above the organic insulating layer IL and in the aperture OP1.

FIG. 15B is a cross-sectional view showing another configuration example.

The configuration example shown in FIG. 15B is different from the configuration example shown in FIG. 15A in respect that the partition 7 located above the organic insulating layer IL is omitted. The partition 7 is provided on the inorganic insulating layer 5 in the aperture OP1.

In FIG. 15A and FIG. 15B, the shape provided in the aperture OP1 may be any one of the shapes of FIG. 9, FIG. 11 and FIG. 12.

FIG. 15C is a cross-sectional view showing another configuration example.

The configuration example shown in FIG. 15C is different from the configuration example shown in FIG. 15A in respect that the partition 7 provided in the aperture OP1 is omitted. The partition 7 is provided on the inorganic insulating layer 5 above the organic insulating layer IL.

### [Second Group]

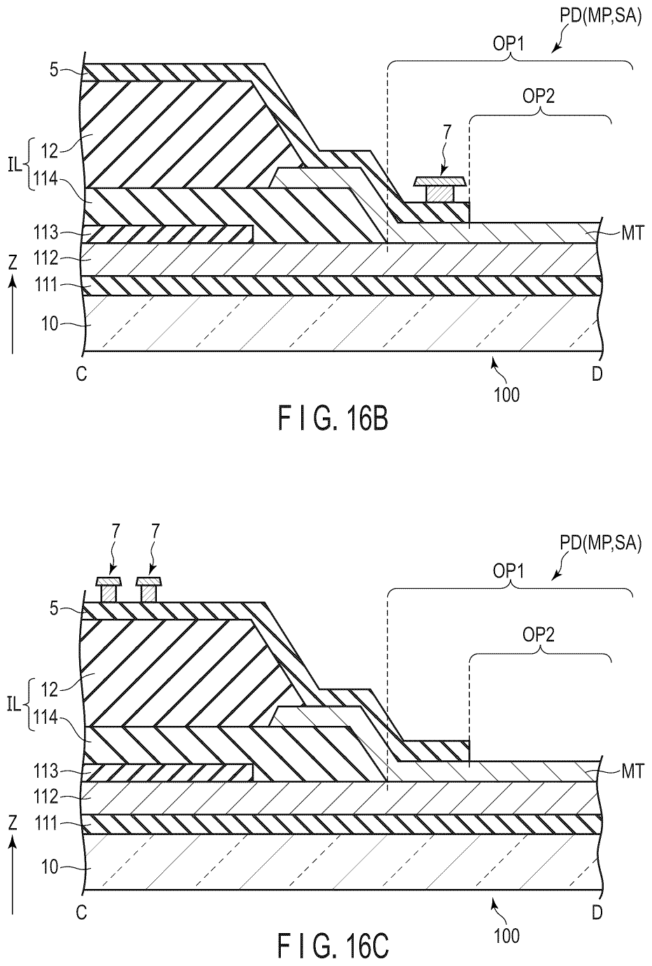

FIG. 16A is a cross-sectional view showing a configuration example of a second group.

The configuration example shown in FIG. 16A is different from the configuration example shown in FIG. 14A in respect that the insulating layer 114 extends toward the pad PD relative to the insulating layer 12. The insulating layer 114 has the aperture OP1. The insulating layer 12 is provided on the insulating layer 114. When this specification focuses attention on the cross-sectional shape of the organic insulating layer IL having the insulating layer 114 and the insulating layer 12, the organic insulating layer IL has a stepwise cross section in which the thickness decreases toward the aperture OP1.

Thickness T1 of the organic insulating layer IL is the sum of the thickness of the insulating layer 114 and the thickness of the insulating layer 12 and corresponds to the length from the upper surface of the insulating layer 113 to substantially a flat upper surface 12A of the insulating layer 12 in the third direction Z.

Thickness T2 of the organic insulating layer IL is the thickness of the insulating layer 114 between the insulating layer 12 and the aperture OP1 and corresponds to the length from the upper surface of the wiring layer 112 to substantially the flat upper surface 114A of the insulating layer 114 in the third direction Z. Thickness T2 is less than thickness T1. The upper surface 114A is located between the upper surface 12A and the aperture OP1 and is located on the lower side than the upper surface 12A.

The inorganic insulating layer 5 covers the insulating layer 12 and has the aperture OP2 from which the metal layer MT is exposed.

The partitions 7 are provided on the inorganic insulating layer 5 above the organic insulating layer IL and in the aperture OP1. In the example shown in the figure, the partition 7 is provided above the upper surface 12A. However, the partition 7 is not provided above the upper surface 114A. It should be noted that the partition 7 may be provided above the upper surface 114A.

The organic insulating layer IL having a stepwise cross section can be formed by, for example, the following method.

First, the insulating layer 114 having the aperture OP1 and the upper surface 114A is formed on the insulating layer 113. Subsequently, the metal layer MT is formed. Subsequently, the insulating layer 12 having the upper surface 12A is formed.

By this process, the organic insulating layer IL having the cross-sectional shape described above is formed.

FIG. 16B is a cross-sectional view showing another configuration example.

The configuration example shown in FIG. 16B is different from the configuration example shown in FIG. 16A in respect that the partition 7 located above the organic insulating layer IL is omitted. The partition 7 is provided on the inorganic insulating layer 5 in the aperture OP1.

FIG. 16C is a cross-sectional view showing another configuration example.

The configuration example shown in FIG. 16C is different from the configuration example shown in FIG. 16A in respect that the partition 7 located in the aperture OP1 is omitted. The partition 7 is provided on the inorganic insulating layer 5 above the organic insulating layer IL.

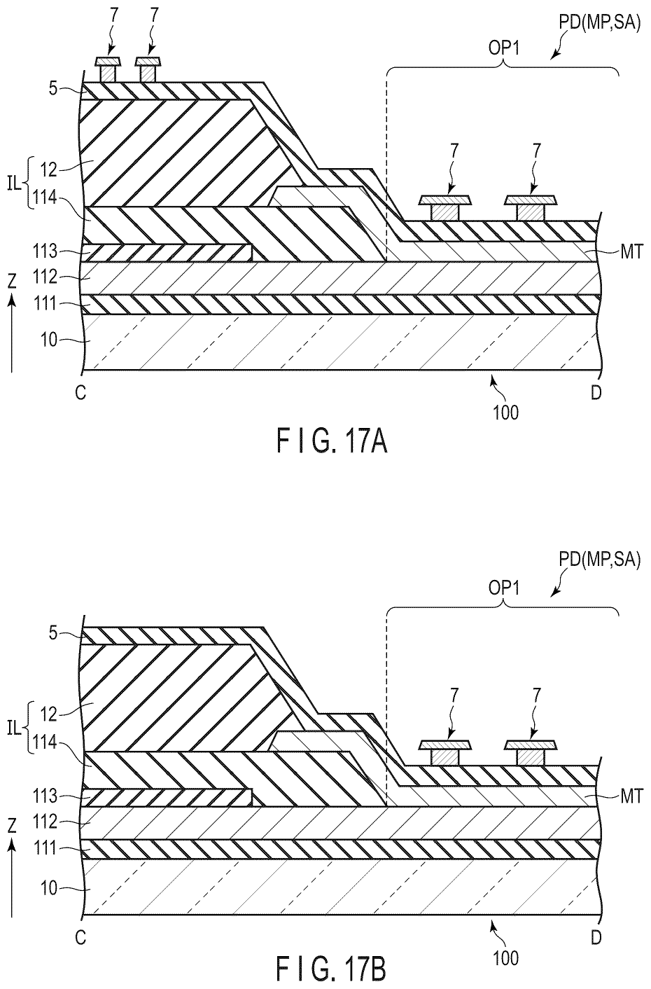

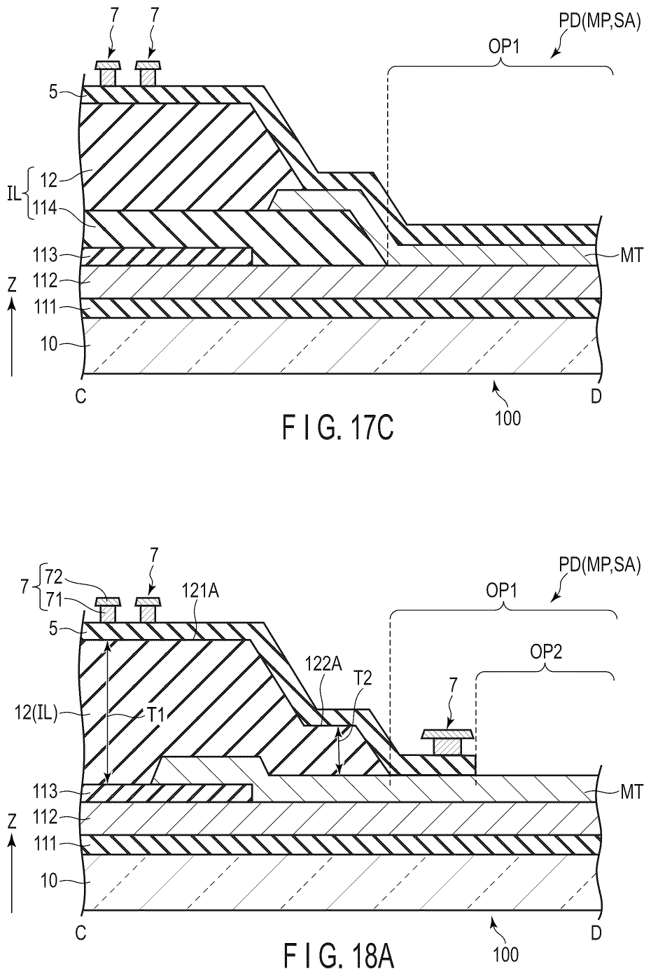

FIG. 17A is a cross-sectional view showing another configuration example.

The configuration example shown in FIG. 17A is different from the configuration example shown in FIG. 16A in respect that no aperture is present in the inorganic insulating layer 5. The partitions 7 are provided on the inorganic insulating layer 5 above the organic insulating layer IL and in the aperture OP1.

FIG. 17B is a cross-sectional view showing another configuration example.

The configuration example shown in FIG. 17B is different from the configuration example shown in FIG. 17A in respect that the partition 7 located above the organic insulating layer IL is omitted. The partition 7 is provided on the inorganic insulating layer 5 in the aperture OP1.

FIG. 17C is a cross-sectional view showing another configuration example.

The configuration example shown in FIG. 17C is different from the configuration example shown in FIG. 17A in respect that the partition 7 provided in the aperture OP1 is omitted. The partition 7 is provided on the inorganic insulating layer 5 above the organic insulating layer IL.

### [Third Group]

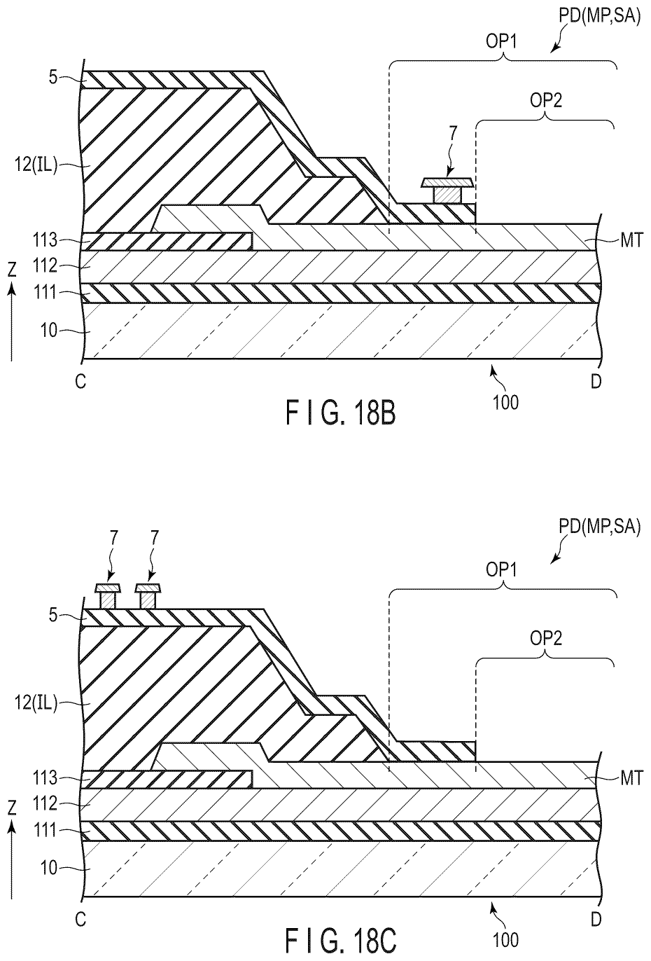

FIG. 18A is a cross-sectional view showing a configuration example of a third group.

The configuration example shown in FIG. 18A is different from the configuration example shown in FIG. 14A in respect that the organic insulating layer IL having a stepwise cross section is a single-layer body of the insulating layer 12. The insulating layer 114 is not present. The insulating layer 12 has the aperture OP1.

Thickness T1 of the organic insulating layer IL corresponds to the length from the upper surface of the insulating layer 113 to substantially the flat upper surface 121A of the insulating layer 12 in the third direction Z.

Thickness T2 of the organic insulating layer IL corresponds to the length from the upper surface of the metal layer MT to substantially the flat upper surface 122A of the insulating layer 12 in the third direction Z. Thickness T2 is less than thickness T1. The upper surface 122A is located between the upper surface 121A and the aperture OP1 and is located on the lower side than the upper surface 121A.

The inorganic insulating layer 5 covers the insulating layer 12 and has the aperture OP2 from which the metal layer MT is exposed.

The partitions 7 are provided on the inorganic insulating layer 5 above the organic insulating layer IL and in the aperture OP1. In the example shown in the figure, the partition 7 is provided above the upper surface 121A. However, the partition 7 is not provided above the upper surface 122A. It should be noted that the partition 7 may be provided above the upper surface 122A.

This insulating layer 12 can be formed by, for example, the following method.

Specifically, for example, an insulating layer is formed by a positive organic material on the whole surface of the mother substrate 100 in which the metal layer MT is formed. Subsequently, the insulating layer is exposed to light. In this exposure process, the amount of exposure of the aperture OP1 is set so as to be the maximum value, and the amount of exposure is set so as to decrease in stages from the aperture OP1 toward the external side. Subsequently, the exposed insulating layer is developed. Subsequently, the insulating layer is baked.

By this process, the insulating layer 12 having the cross-sectional shape described above is formed.

FIG. 18B is a cross-sectional view showing another configuration example.

The configuration example shown in FIG. 18B is different from the configuration example shown in FIG. 18A in respect that the partition 7 located above the organic insulating layer IL is omitted. The partition 7 is provided on the inorganic insulating layer 5 in the aperture OP1.

FIG. 18C is a cross-sectional view showing another configuration example.

The configuration example shown in FIG. 18C is different from the configuration example shown in FIG. 18A in respect that the partition 7 provided in the aperture OP1 is omitted. The partition 7 is provided on the inorganic insulating layer 5 above the organic insulating layer IL.

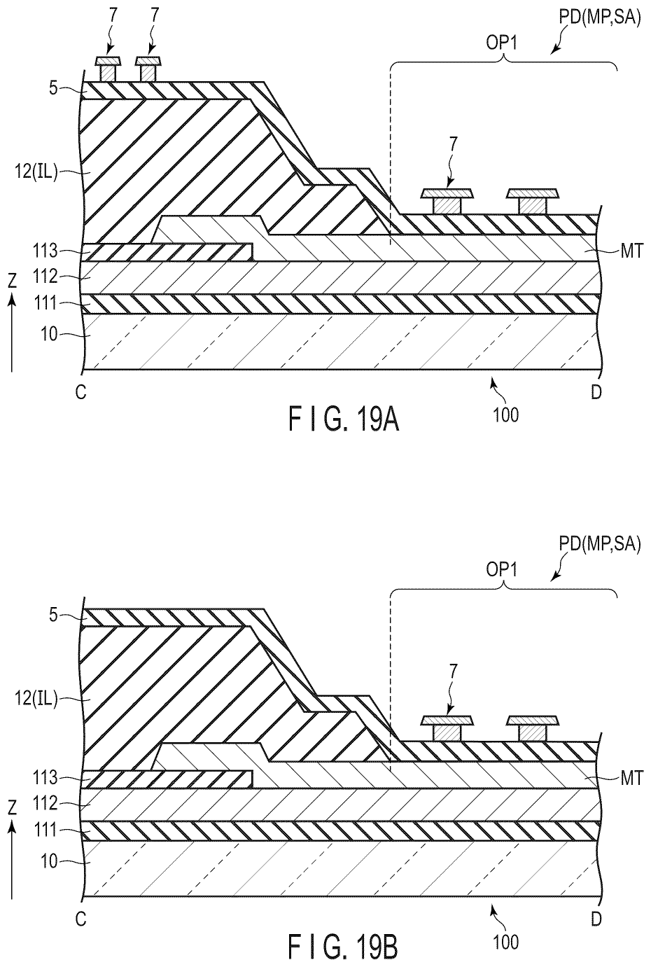

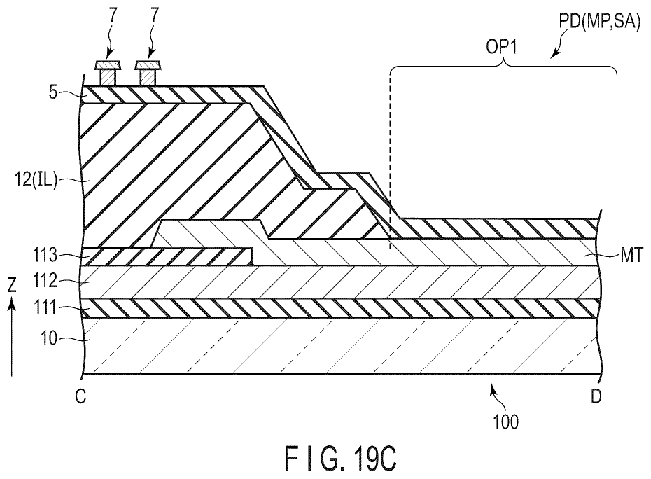

FIG. 19A is a cross-sectional view showing another configuration example.

The configuration example shown in FIG. 19A is different from the configuration example shown in FIG. 18A in respect that no aperture is present in the inorganic insulating layer 5. The partitions 7 are provided on the inorganic insulating layer 5 above the organic insulating layer IL and in the aperture OP1.

FIG. 19B is a cross-sectional view showing another configuration example.

The configuration example shown in FIG. 19B is different from the configuration example shown in FIG. 19A in respect that the partition 7 located above the organic insulating layer IL is omitted. The partition 7 is provided on the inorganic insulating layer 5 in the aperture OP1.

FIG. 19C is a cross-sectional view showing another configuration example.

The configuration example shown in FIG. 19C is different from the configuration example shown in FIG. 19A in respect that the partition 7 provided in the aperture OP1 is omitted. The partition 7 is provided on the inorganic insulating layer 5 above the organic insulating layer IL.

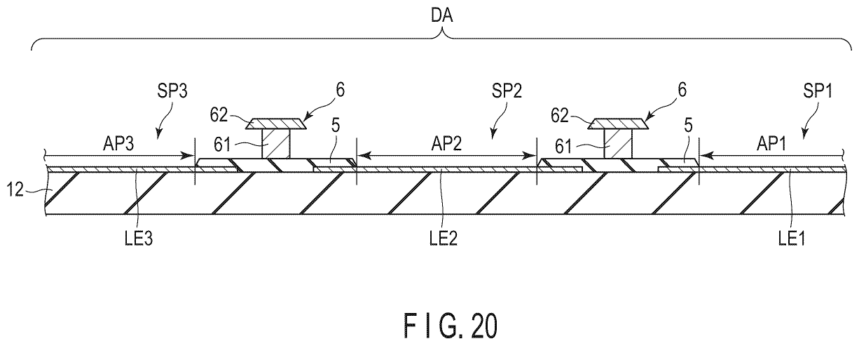

Now, this specification explains the manufacturing method of the display device DSP with reference to FIG. 20 to FIG. 25. In FIG. 20 to FIG. 25, the illustration lower than the insulating layer 12 is omitted.

First, as shown in FIG. 20, the lower electrode LE1 of subpixel SP1, the lower electrode LE2 of subpixel SP2 and the lower electrode LE3 of subpixel SP3 are formed on the insulating layer 12 after forming the insulating layer 12 in the display area DA. Subsequently, the inorganic insulating layer 5 is formed.

The insulating layer 12 and the inorganic insulating layer 5 are formed in the surrounding area SA and the margin portion MP in addition to the display area DA. The formation method of the organic insulating layer IL including the insulating layer 12 in the surrounding area SA and the margin portion MP is, for example, as explained with reference to FIG. 14A etc. The process of forming the organic insulating layer IL includes the process of forming the aperture OP1 overlapping the metal layer MT.

Subsequently, the partition 6 which has the lower portion 61 located on the inorganic insulating layer 5 and the upper portion 62 located on the lower portion 61 is formed in the display area DA. At this time, the partition 7 having the lower portion 71 and the upper portion 72 is formed at the same time as the partition 6 in the surrounding area SA and the margin portion MP. The partition 7 is formed above the organic insulating layer IL as shown in FIG. 7 etc., and is formed in the aperture OP1 as shown in FIG. 10 etc.

Subsequently, the apertures AP1, AP2 and AP3 are formed in the inorganic insulating layer 5. The aperture AP1 overlaps the lower electrode LE1 of subpixel SP1. The aperture AP2 overlaps the lower electrode LE2 of subpixel SP2. The aperture AP3 overlaps the lower electrode LE3 of subpixel SP3. It should be noted that the formation process of the apertures AP1, AP2 and AP3 may be performed before the formation process of the partition 6. At the same time as the formation of the aperture AP1 etc., on the inorganic insulating layer 5, the aperture OP2 of each pad PD is also formed.

Subsequently, the display element 201 is formed.

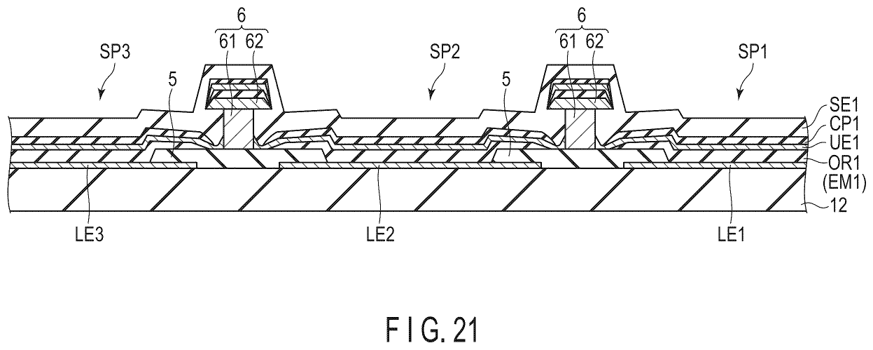

First, as shown in FIG. 21, the organic layer OR1 is formed by depositing the materials for forming the hole injection layer, the hole transport layer, the electron blocking layer, the light emitting layer EM1, the hole blocking layer, the electron transport layer, the electron injection layer, etc., on the lower electrode LE1 in series using the partition 6 as a mask.

Subsequently, the upper electrode UE1 is formed by depositing a mixture of magnesium and silver on the organic layer OR1 using the partition 6 as a mask. The upper electrode UE1 covers the organic layer OR1 and is in contact with the lower portion 61.

Subsequently, the cap layer CP1 is formed by depositing a high-refractive material and a low-refractive material in series on the upper electrode UE1 using the partition 6 as a mask.

These organic layer OR1, upper electrode UE1 and cap layer CP1 are continuously formed while maintaining a vacuum environment.

Subsequently, the sealing layer SE1 is formed so as to continuously cover the cap layer CP1 and the partition 6.

The organic layer OR1, the upper electrode UE1 and the cap layer CP1 are divided by the partition 6 having an overhang shape.

The materials which are emitted from an evaporation source when the organic layer OR1, the upper electrode UE1 and the cap layer CP1 are formed by vapor deposition are blocked by the upper portion 62. Thus, each of the organic layer OR1, the upper electrode UE1 and the cap layer CP1 is partly stacked on the upper portion 62. The organic layer OR1, upper electrode UE1 and cap layer CP1 located on the upper portion 62 are spaced apart from the organic layer OR1, upper electrode UE1 and cap layer CP1 located immediately above the lower electrode LE1.

These organic layer OR1, upper electrode UE1, cap layer CP1 and sealing layer SE1 are formed in the surrounding area SA and the margin portion MP in addition to the display area DA.

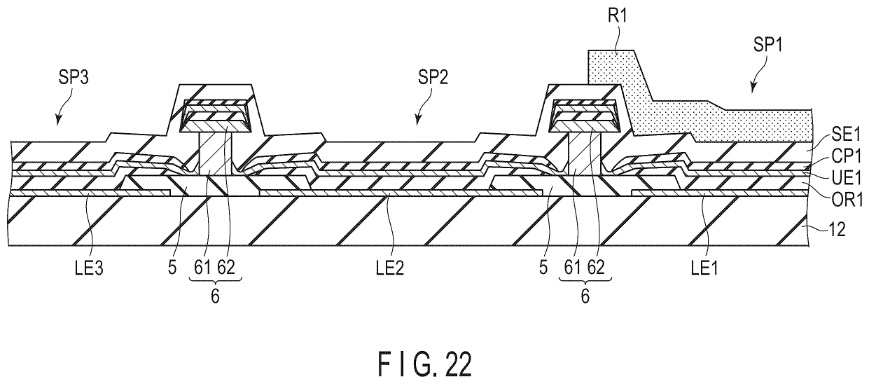

Subsequently, as shown in FIG. 22, a resist R1 patterned into a predetermined shape is formed on the sealing layer SE1. The resist R1 overlaps subpixel SP1 and part of the partition 6 around subpixel SP1.

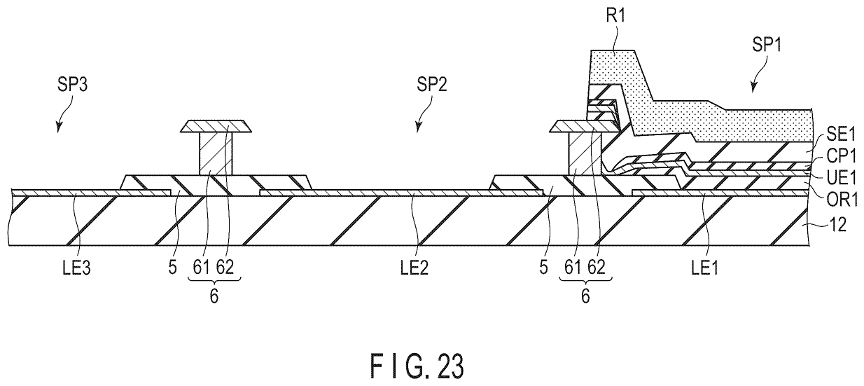

Subsequently, as shown in FIG. 23, the sealing layer SE1, cap layer CP1, upper electrode UE1 and organic layer OR1 exposed from the resist R1 are removed in series by performing etching using the resist R1 as a mask. In this manner, the lower electrode LE2 of subpixel SP2 and the lower electrode LE3 of subpixel SP3 are exposed.

Subsequently, the resist R1 is removed. By this process, the display element 201 is formed in subpixel SP1.

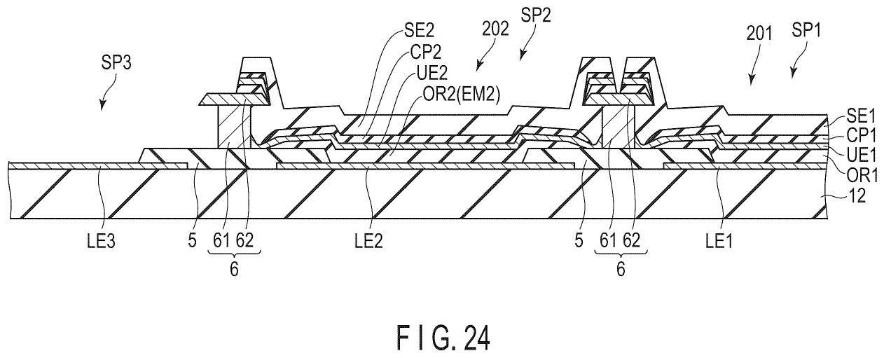

Subsequently, as shown in FIG. 24, the display element 202 is formed. The procedure of forming the display element 202 is similar to that of forming the display element 201. Specifically, the organic layer OR2 including the light emitting layer EM2, the upper electrode UE2, the cap layer CP2 and the sealing layer SE2 are formed in order on the lower electrode LE2. Subsequently, a resist is formed on the sealing layer SE2. The sealing layer SE2, the cap layer CP2, the upper electrode UE2 and the organic layer OR2 are patterned in series by etching using the resist as a mask. After this patterning, the resist is removed. In this manner, the display element 202 is formed in subpixel SP2, and the lower electrode LE3 of subpixel SP3 is exposed.

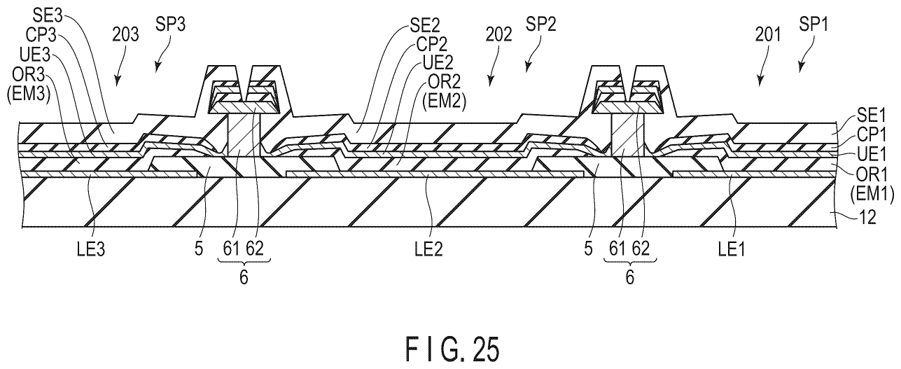

Subsequently, as shown in FIG. 25, the display element 203 is formed. The procedure of forming the display element 203 is similar to that of forming the display element 201. Specifically, the organic layer OR3 including the light emitting layer EM3, the upper electrode UE3, the cap layer CP3 and the sealing layer SE3 are formed in order on the lower electrode LE3. Subsequently, a resist is formed on the sealing layer SE3. The sealing layer SE3, the cap layer CP3, the upper electrode UE3 and the organic layer OR3 are patterned in series by etching using the resist as a mask. After this patterning, the resist is removed. By this process, the display element 203 is formed in subpixel SP3.

Subsequently, the resin layer 13, sealing layer 14 and resin layer 15 shown in FIG. 3 are formed in order. By this process, the display device DSP is completed.

In the manufacturing process described above, this specification assumes a case where the display element 201 is formed firstly, and the display element 202 is formed secondly, and the display element 203 is formed lastly. However, the formation order of the display elements 201, 202 and 203 is not limited to this example.

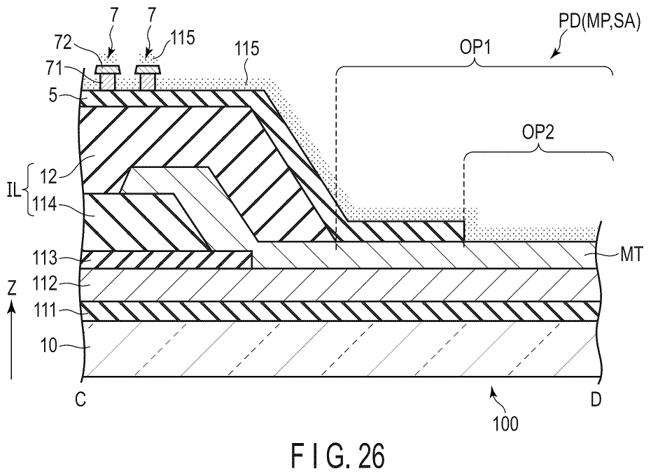

FIG. 26 is a cross-sectional view for explaining a state in which a multilayer film 115 is formed in the pad PD shown in FIG. 7.

In the process of forming each of the display elements 201, 202 and 203 described above, the multilayer film 115 is formed in the margin portion MP and the surrounding area SA as well. Here, the multilayer film 115 includes, for example, the organic layer OR1, upper electrode UE1 and cap layer CP1 for forming the display element 201 explained with reference to FIG. 21. The multilayer film 115 is formed on the inorganic insulating layer 5, the partition 7 and the metal layer MT.

As explained with reference to FIG. 21, the multilayer film 115 is divided by the partition 7 having an overhang shape. The materials which are emitted from the evaporation source when the organic layer OR1, the upper electrode UE1 and the cap layer CP1 are formed by vapor deposition are blocked by the upper portion 72 of the partition 7. Thus, each of the organic layer OR1, the upper electrode UE1 and the cap layer CP1 is partly stacked on the upper portion 72. The organic layer OR1, upper electrode UE1 and cap layer CP1 located on the upper portion 72 are spaced apart from the organic layer OR1, upper electrode UE1 and cap layer CP1 located on the inorganic insulating layer 5. By this configuration, the multilayer film 115 is partly divided.

In particular, when the partition 7 is formed into a grating shape as shown in FIG. 6 etc., a plurality of closed areas surrounded by the partition 7 are formed. In this case, the multilayer film 115 located in each closed area is divided from the multilayer film 115 located on the partition 7. As a result, the multilayer film 115 is divided into some segments.

Compared to a case where the multilayer film 115 is not divided by the partition 7, the area of the continuous multilayer film 115 is reduced, and a stress which could be generated in the multilayer film 115 is dispersed. In addition, as the inorganic insulating layer 5 and the multilayer film 115 located on the inorganic insulating layer 5 are pressed by the partition 7, the uplift of the inorganic insulating layer 5 and the uplift of the multilayer film 115 from the inorganic insulating layer 5 are prevented. Further, the sealing layer SE1 which is formed after the formation of the multilayer film 115 presses the multilayer film 115 with the partition 7. Thus, the removal of the multilayer film 115 and the sealing layer SE1 from the inorganic insulating layer 5 can be prevented.

Here, this specification explains problems which could occur when the multilayer film 115 is raised from the inorganic insulating layer 5 and broken. The multilayer film 115 removed from the inorganic insulating layer 5 floats inside the manufacturing device as a foreign substance and could be a contaminant source. If the floating foreign substance is attached to the processing substrate, various defects could be caused.

To the contrary, in the embodiment, the removal of the multilayer film 115 can be prevented in the pad area including the pads PD. This configuration prevents the contamination of the manufacturing device and the generation of undesired foreign substances. In this manner, the reduction in reliability is prevented.

Even in a case where the multilayer film 115 includes the organic layer OR2, upper electrode UE2 and cap layer CP2 for forming the display element 202, similar effects can be obtained.

In addition, even in a case where the multilayer film 115 includes the organic layer OR3, upper electrode UE3 and cap layer CP3 for forming the display element 203, similar effects can be obtained.

Here, the effect of preventing the removal of the multilayer film 115 is explained with respect to the configuration example shown in FIG. 6 and FIG. 7. Similar effects can be also obtained with respect to the other configuration examples.

In the configuration examples shown in FIG. 8 and the like, the linear partitions 7 are arranged in a staggered manner in the small space between adjacent pads PD. When the linear partitions 7 are provided in a space where the partition 7 having a grating shape cannot be provided in this manner, the multilayer film 115 is partly divided, and the removal of the multilayer film 115 can be prevented as described above.

Further, the process of forming the resist R1 shown in FIG. 22 includes the process of applying the liquid resist R1. When the linear partitions 7 are arranged in a staggered manner, the expansion of the applied resist R1 is not easily blocked compared to a case where the partition 7 is formed into a continuous long linear shape, and further, the resist R1 expands while being in contact with the partitions 7. This configuration can prevent a problem in which an undesired cavity is formed in the resist R1.

In the configuration example shown in FIG. 9 and FIG. 10, the partition 7 overlapping the aperture OP1 (or the pad PD) of the organic insulating layer IL is provided. For this reason, similarly, the multilayer film 115 is divided in the aperture OP1, and the removal of the multilayer film 115 can be prevented as described above.

In the configuration example shown in FIG. 11, the partition 7 overlapping the aperture OP1 (or the pad PD) of the organic insulating layer IL is divided into a plurality of segments. For this reason, the expansion of the applied resist R1 is not easily blocked in the aperture OP1.

In the configuration example shown in FIG. 12 and FIG. 13, the partition 7 overlapping the aperture OP1 (or the pad PD) of the organic insulating layer IL is formed into a grating shape. Thus, the multilayer film 115 can be divided into some segments in the aperture OP1. It should be noted that, in the configuration example shown in FIG. 12, the metal layer MT in the pad PD is covered with the inorganic insulating layer 5. Thus, a process such as inspection using the pad PD is performed before the formation of the inorganic insulating layer 5.

Further, in each of the configuration examples explained in the first group, the second group and the third group, the organic insulating layer IL has a stepwise cross section in which the thickness decreases toward the aperture OP1. Thus, the formation of a steep step is prevented. The elongation of the organic insulating layer IL is less as the thickness decreases. Thus, when the multilayer film 115 is formed on the organic insulating layer IL, the distortion of the multilayer film 115 is less, and the local concentration of stress can be prevented in the multilayer film 115. By this configuration, the removal of the multilayer film 115 from the inorganic insulating layer 5 can be prevented.

In the embodiment described above, for example, the insulating layer 114 corresponds to the first layer of an organic insulating layer. The insulating layer 12 corresponds to the second layer of the organic insulating layer. The partition 7 corresponds to a first partition. The lower portion 71 corresponds to a first lower portion. The upper portion 72 corresponds to a first upper portion. The partition 6 corresponds to a second partition. The lower portion 61 corresponds to a second lower portion. The upper portion 62 corresponds to a second upper portion.

As explained above, the embodiment can provide a display device which can prevent the reduction in reliability and a manufacturing method of such a display device.

All of the display devices and the manufacturing methods of the display devices that can be implemented by a person of ordinary skill in the art through arbitrary design changes to the display device and the manufacturing method of the display device described above as the embodiments of the present invention come within the scope of the present invention as long as they are in keeping with the spirit of the present invention.

Various modification examples which may be conceived by a person of ordinary skill in the art in the scope of the idea of the present invention will also fall within the scope of the invention. For example, even if a person of ordinary skill in the art arbitrarily modifies the above embodiments by adding or deleting a structural element or changing the design of a structural element, or by adding or omitting a step or changing the condition of a step, all of the modifications fall within the scope of the present invention as long as they are in keeping with the spirit of the invention.

Further, other effects which may be obtained from the above embodiments and are self-explanatory from the descriptions of the specification or can be arbitrarily conceived by a person of ordinary skill in the art are considered as the effects of the present invention as a matter of course.

Examples of the mother substrate obtained from the configuration disclosed in this specification are additionally described below.

(A)

A mother substrate for a display device, comprising:
a panel portion having a display area which displays an image and a surrounding area located on an external side relative to the display area;
a margin portion located on an external side relative to the panel portion;
an organic insulating layer provided over the panel portion and the margin portion;
a lower electrode provided on the organic insulating layer in the display area;
an organic layer provided on the lower electrode and including a light emitting layer;
an upper electrode provided on the organic layer;
a first partition having a first lower portion and a first upper portion which is provided on the first lower portion and protrudes from a side surface of the first lower portion; and
a metal layer provided in the margin portion and overlapping an aperture of the organic insulating layer, wherein
the first partition is provided in the aperture.

(B)

A mother substrate for a display device, comprising:
a panel portion having a display area which displays an image and a surrounding area located on an external side relative to the display area;
a margin portion located on an external side relative to the panel portion;
an organic insulating layer provided over the panel portion and the margin portion;
a lower electrode provided on the organic insulating layer in the display area;
an organic layer provided on the lower electrode and including a light emitting layer;
an upper electrode provided on the organic layer;
a first partition having a first lower portion and a first upper portion which is provided on the first lower portion and protrudes from a side surface of the first lower portion; and
a metal layer provided in the margin portion and overlapping an aperture of the organic insulating layer, wherein
the first partition is provided above the organic insulating layer in at least one of the margin portion and the surrounding area.

What is claimed is:

1. A display device comprising:
a substrate;
an organic insulating layer provided over a display area which displays an image and a surrounding area located on an external side relative to the display area above the substrate;
a lower electrode provided on the organic insulating layer in the display area;
an organic layer provided on the lower electrode and including a light emitting layer;
an upper electrode provided on the organic layer;
a first partition provided in the surrounding area and having a first lower portion and a first upper portion which is provided on the first lower portion and protrudes from a side surface of the first lower portion; and
a metal layer provided in the surrounding area and overlapping an aperture of the organic insulating layer, wherein
the first partition is provided in the aperture.

2. The display device of claim 1, wherein
the first partition is formed into a loop shape along a rim of the aperture in plan view.

3. The display device of claim 1, wherein
the first partition has a plurality of segments formed along a rim of the aperture in plan view.

4. The display device of claim 1, wherein
the first partition is formed into a grating shape in plan view.

5. A display device comprising:
a substrate;
an organic insulating layer provided over a display area which displays an image and a surrounding area located on an external side relative to the display area above the substrate;
a lower electrode provided on the organic insulating layer in the display area;
an organic layer provided on the lower electrode and including a light emitting layer;
an upper electrode provided on the organic layer;
a first partition provided in the surrounding area and having a first lower portion and a first upper portion which is provided on the first lower portion and protrudes from a side surface of the first lower portion; and
a metal layer provided in the surrounding area and overlapping an aperture of the organic insulating layer, wherein
the first partition is provided above the organic insulating layer.

6. The display device of claim 5, wherein
the first partition is formed into a grating shape in plan view.

7. The display device of claim 5, wherein
the first partition is further provided in the aperture.

8. The display device of claim 1, further comprising an inorganic insulating layer which covers the organic insulating layer, wherein
the first partition is provided on the inorganic insulating layer.

9. The display device of claim 8, wherein
the inorganic insulating layer is provided in the display area and has an aperture overlapping the lower electrode.

10. The display device of claim 9, further comprising a second partition having a second lower portion which is provided on the inorganic insulating layer and is formed of a conductive material and a second upper portion which is provided on the second lower portion and protrudes from a side surface of the second lower portion, wherein
the lower electrode, the organic layer and the upper electrode are surrounded by the second partition, and
the upper electrode is in contact with the second lower portion of the second partition.

11. The display device of claim 1, further comprising an inorganic insulating layer which covers the organic insulating layer and covers the metal layer exposed from the aperture of the organic insulating layer, wherein
the first partition provided in the aperture is formed into a grating shape and is provided on the inorganic insulating layer.

12. The display device of claim 1, wherein
the organic insulating layer has a first layer and a second layer located on the first layer, and further has a stepwise cross section in which a thickness decreases toward the aperture.

13. The display device of claim 1, wherein
the organic insulating layer is a single-layer body and has a stepwise cross section in which a thickness decreases toward the aperture.

14. A manufacturing method of a display device, comprising:
forming a metal layer above a substrate;
forming an organic insulating layer over a display area which displays an image and a surrounding area located on an external side relative to the display area;
forming a lower electrode on the organic insulating layer in the display area;
forming a first partition having a first lower portion located in the surrounding area and a first upper portion which is located on the first lower portion and protrudes from a side surface of the first lower portion;
forming an organic layer including a light emitting layer on the lower electrode; and
forming an upper electrode on the organic layer, wherein
the forming the organic insulating layer includes a process of forming an aperture overlapping the metal layer in the surrounding area.

15. The manufacturing method of claim 14, wherein
the first partition is formed in the aperture.

16. The manufacturing method of claim 14, wherein
the first partition is formed above the organic insulating layer.

17. The manufacturing method of claim 14, further comprising, after forming the lower electrode and before forming the first partition,
forming an inorganic insulating layer which covers the organic insulating layer and has an aperture overlapping the lower electrode.

18. The manufacturing method of claim 17, further comprising, after forming the inorganic insulating layer and before forming the organic layer,
forming the first partition on the inorganic insulating layer, and a second partition having a conductive second lower portion located on the inorganic insulating layer and a second upper portion located on the second lower portion and protruding from a side surface of the second lower portion, wherein
the organic layer and the upper electrode are formed by vapor deposition using the second partition as a mask.

19. The manufacturing method of claim 18, further comprising, after forming the upper electrode,
forming a cap layer on the upper electrode by performing vapor deposition using the second partition as a mask, and
forming a sealing layer which covers the second partition and the cap layer.

20. The manufacturing method of claim 19, further comprising,
forming a patterned resist on the sealing layer, and
removing part of the sealing layer, part of the cap layer, part of the upper electrode and part of the organic layer in series by performing etching using the resist as a mask.
